(19) United States
(12) Patent Application Publication
(10) Pub. No.: US 2005/0035410 A1
(43) Pub. Date: Feb. 17, 2005

(54) Semiconductor diode with reduced leakage

(76) Inventors: Yee-Chia Yeo, Hsin-Chu (TW); Fu-Liang Yang, Hsin-Chu (TW); Chenming Hu, Hsin-Chu (TW)

Correspondence Address: SLATER & MATSIL, L.L.P., 17950 PRESTON ROAD, SUITE 1000, DALLAS, TX, 75252, US

(21) Appl. No.: 10/641,813

(22) Filed: Aug. 15, 2003

(51) Int. Cl. H01L 29/76; H01L 21/8238

(52) U.S. Cl. 257/355; 257/367; 438/199

(57) ABSTRACT

A diode 100 is formed on a silicon-on-insulator substrate that includes a silicon layer overlying an insulator layer 142. An active region is formed in the silicon layer and includes a p-doped region 108 and an n-doped region 106 separated by a body region 110. A high permittivity gate dielectric 114 overlies the body region 110 and a gate electrode 112 overlies the gate dielectric 114. As an example, the diode can be used for ESD protection.

### TECHNICAL FIELD

The present invention relates to the field of semiconductor devices, and more specifically, to a semiconductor diode device for electrostatic discharge protection in advanced complementary metal-oxide-semiconductor (CMOS) technologies.

### BACKGROUND

Transistor size reduction has resulted in the thinning of insulator layers such as the gate dielectric. These thinner dielectric layers fail at lower voltages. Consequently, device scaling increases circuit sensitivity to voltage stress, electrical overstress (EOS), and electrostatic discharge (ESD). These types of failures are a major concern in advanced semiconductor technology. This is especially true for integrated circuit (IC) chips that interface with other chips or signals with voltages above that of the IC chip itself.

Silicon based ICs are particularly susceptible to electrostatic discharge damage, for example in the situation where a user of a device containing an integrated circuit develops a static charge on their body and subsequently comes in contact with the device containing the integrated circuit. The electrostatic discharge induced in a human body may produce a voltage in excess of 5000 volts. Such a high instantaneous voltage may catastrophically damage the integrated circuit.

Therefore, IC chips usually include protection devices or diodes in interface circuits to provide the IC chip with added ESD protection. U.S. Pat. No. 5,629,544, entitled “Semiconductor diode with silicide films and trench isolation,” issued to Voldman et al. teaches the use of diode structures bound by poly-silicon for the protection of bulk silicon and silicon-on-insulator (SOI) circuits. U.S. Pat. No. 6,015,993 and U.S. Pat. No. 6,232,163, both issued to Voldman et al., discuss a high voltage tolerant diode structure for mixed-voltage and mixed signal and analog/digital applications. These prior arts are applicable to bulk and SOI transistor technologies.

FIG. 1a shows the cross-sectional view of a prior art diode 10 structure fabricated on bulk silicon substrate 12. FIG. 1b shows the cross-sectional view of a prior art diode structure 14 fabricated on a silicon-on-insulator (SOI) wafer that includes substrate 16 and buried oxide 18. This device is commonly known as the lateral unidirectional bipolar insulated gate type transistor or lubistor. The structures of FIGS. 1a and 1b are also known as gated diodes, since a gate stack 20 overlies the body region of the diode.

In both these structures, the n+ region 22 and p+ region 24 are formed on opposite sides of the poly-silicon (poly-Si) gate stack 20, which is separated from the substrate by a dielectric 26, typically silicon oxide. The n+ and p+ regions 22 and 24 in the substrate in FIG. 1a and in the active layer in FIG. 1b are used as the two terminals of the diode. The poly-Si gate stack 20 in the structures of FIGS. 1a and 1b may be connected to the cathode (e.g., n+ region 22), for example.

### SUMMARY OF THE INVENTION

The present invention provides a semiconductor diode for electrostatic discharge protection that is compatible with the fabrication processes of advanced transistors and has reduced reverse leakage current.

Aspects of the invention can be found in a semiconductor diode that has a substrate with a body region formed in part of the substrate. A high permittivity gate dielectric lies between the body region and a gate electrode. P-doped and n-doped regions are adjacent opposite sides of the body region. The substrate may be bulk semiconductor, bulk silicon, SiGe, or silicon-on-insulator. The high permittivity dielectric may be aluminum oxide, hafnium oxide, hafnium oxynitride, hafnium silicate, zirconium oxide, zirconium oxynitride, zirconium silicate, yttrium oxide, lanthanum oxide, cerium oxide, titanium oxide, tantalum oxide, or combinations thereof. The gate electrode may be poly-crystalline silicon, poly-crystalline silicon-germanium, a metal, a metallic nitride, a metallic silicide, a metallic oxide, or combinations thereof. The gate electrode may have p-doped and n-doped regions.

Further aspects of the invention may be found in a diode for electrostatic discharge protection that has a body region formed in the silicon layer of a silicon-on-insulator substrate. A gate electrode is separated from the body region by a high permittivity gate dielectric. Regions located oppositely adjacent to the body region are doped, respectively, with p-type and n-type dopants.

Still further aspects of the invention can be found in a method of making a diode. Steps of the method include providing a silicon-on-insulator substrate and creating an active region in the silicon layer of the substrate. A high permittivity gate dielectric is formed on the active region and a gate electrode is deposited on the gate dielectric. P-doped and n-doped regions are created in the active regions.

Aspects of the invention may be found where the p-doped and n-doped regions may be created by the steps of forming an implant mask and doping a first portion of the active region, then forming another implant mask and doping a second portion of the active region. Other aspects of the invention may be found in the inclusion of the further step of forming isolation regions surrounding the active region.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIGS. 1a and 1b are cross section views of diodes according to the prior art;

FIGS. 2a and 2b are schematic views of applications of diode devices for electrostatic discharge protection;

FIG. 3 is a cross section view of a gated diode indicating leakage current paths;

FIG. 4 is a cross section view of an embodiment of the present invention;

FIG. 5 is an energy band diagram;

FIG. 6 is a cross section view of another embodiment of the invention;

FIG. 7 is a cross section view of an alternate embodiment of the present invention;

FIG. 8 is a cross section view of a device embodying the invention;

FIG. 9 is a flowchart of steps in the process of fabricating a device according to the present invention; and

FIGS. 10a through 10f are cross section views of the results of steps in the process of fabricating a device according to the present invention.

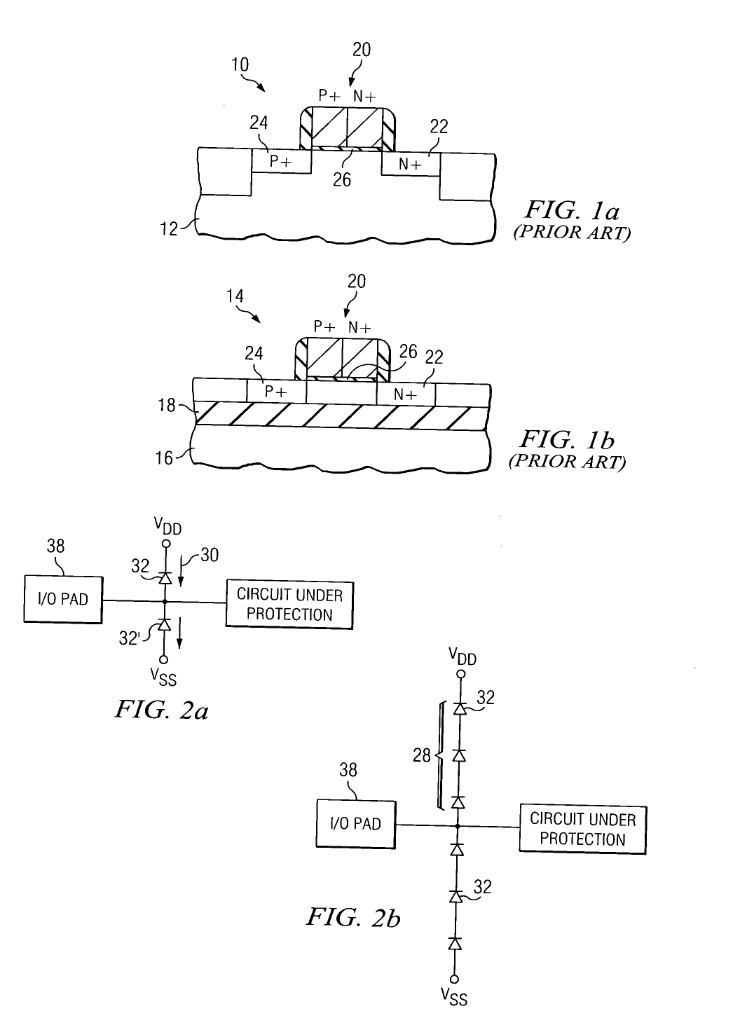

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a gated diode for use in protecting semiconductor devices from electrostatic discharge damage. The invention may also be applied, however, to other semiconductor components for which reduced leakage current is a desirable design goal.

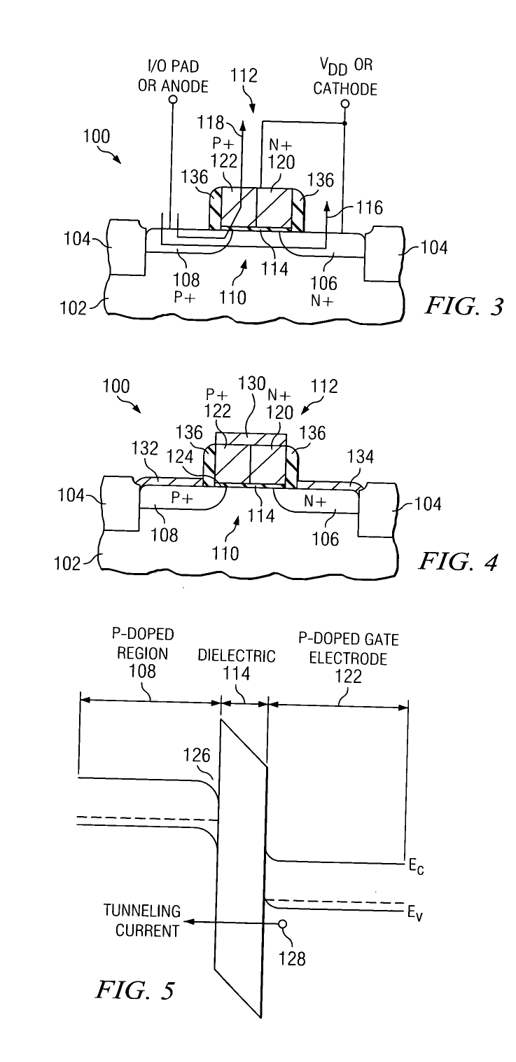

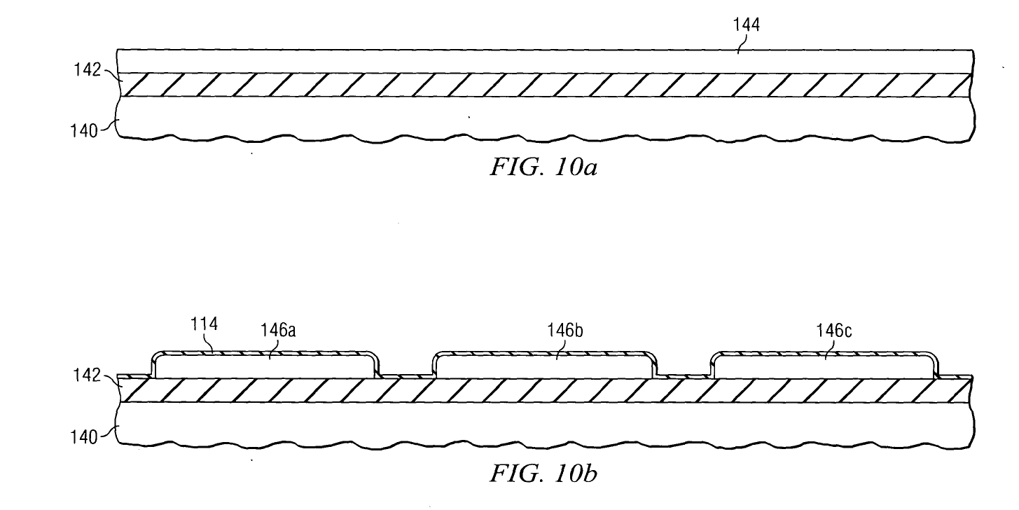

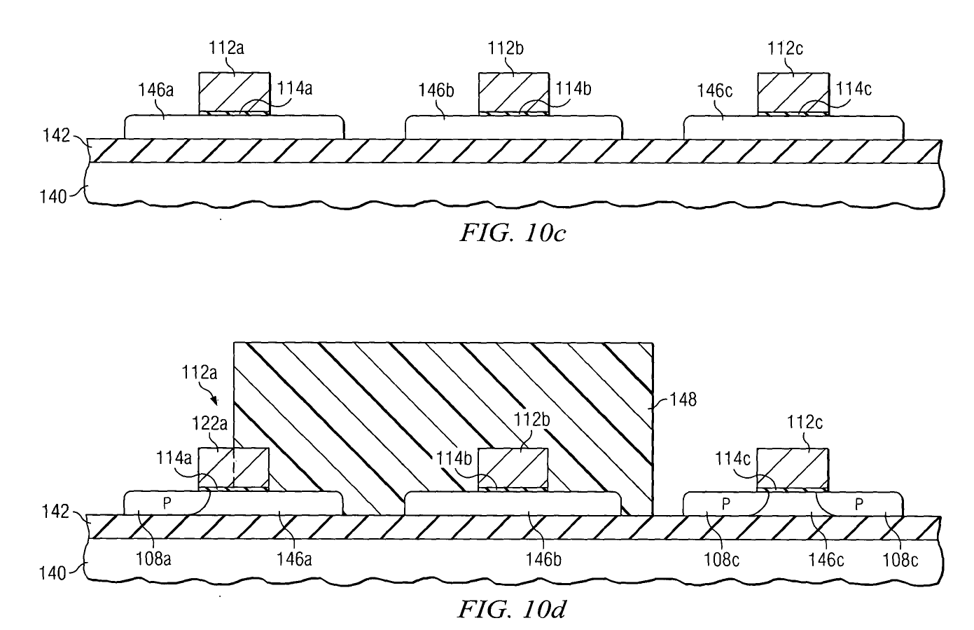

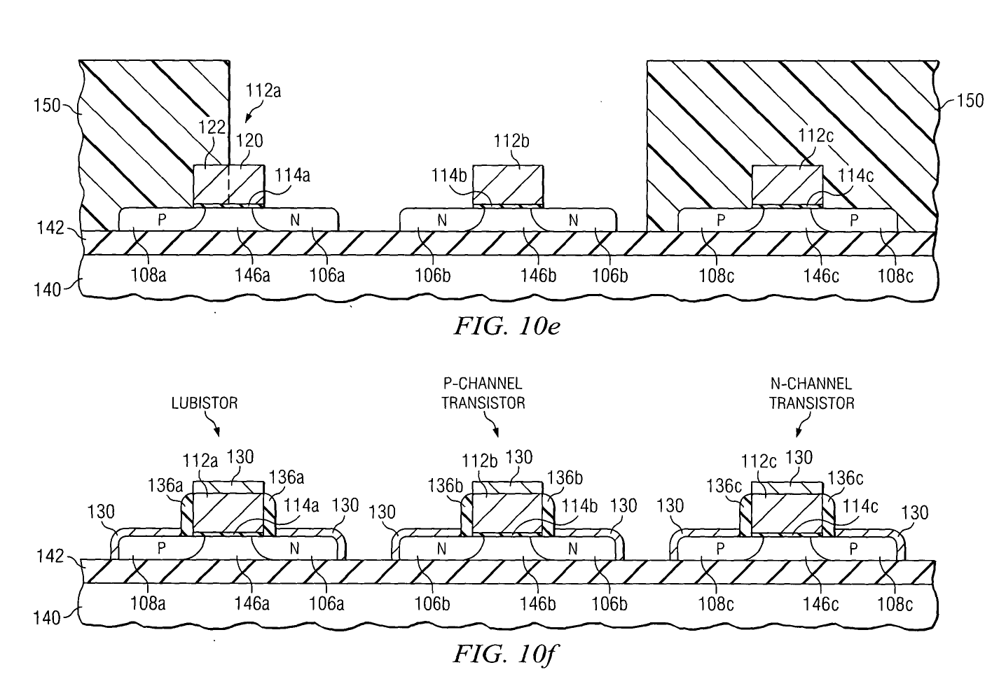

As will be discussed in greater detail below, the preferred embodiment of the present invention relates to a diode that has reduced leakage. FIGS. 2a and 2b illustrate how these diodes can be used in for electrostatic discharge (ESD) protection. FIG. 3 shows examples of leakage paths. FIGS. 4-8 show various embodiment diodes and FIGS. 9 and 10a-10f are used to discuss one embodiment fabrication process.

FIGS. 2a and 2b show examples of how the diodes are deployed for protection of integrated circuits. Referring first to FIG. 2a, a first diode 32 is coupled between a supply voltage source V_{DD} and an I/O pad 38. For example, diode 32 can include a p-doped region coupled to I/O pad 38 and an n-doped region coupled to V_{DD}. A second diode 32′ is coupled between the I/O pad 38 and a reference voltage V_{SS} or ground. In this case, the p-doped region is coupled to ground and the n-doped region is coupled to the pad.

The I/O pad 38 is provided to indicate any node that might be subject to a high voltage. The most typical of these nodes are the inputs and outputs between the chip and the outside world (e.g., external circuitry when connected to a system or handling devices when the system is being assembled). The pad 38 is indicated as being an I/O pad, which stands for input/output. It is noted, however, that in this patent the term I/O is meant to include pads for input only, output only or both input and output (or any other node that might be subject to a high voltage).

FIG. 2b shows an alternate embodiment where a diode string 28 is used in place of the single diodes 32 and 32′ of FIG. 2b. In the preferred embodiment, each of the diodes 32 in the diode string 28 comprises a diode of the present invention, as will be discussed below. In an alternate embodiment, only one or more (but not all) of the diodes 32 are diodes of the present invention and the remainder are not.

Semiconductor diodes 32 used for ESD protection should have low series resistance, low sub-threshold leakage, and low reverse leakage. The series resistance is an important factor for achieving good ESD performance. ESD protection levels improve with a reduction in diode series resistance. The series resistance characteristic is especially important in a mixed voltage environment where diode strings 28 are used and where the series resistance of each diode adds degrading ESD performance.

Diode resistance is largely determined by the size of the diode, the resistivity of the material constituting the diode body, the distance of the current path, and the resistance of silicide films or other contacts to n+ and p+ diffusions. In addition, reverse leakage is another important factor. Reverse diode leakage current 30 is indicated in FIG. 2a. A high reverse leakage results in high standby power consumption. In certain advanced IC chip applications, low power consumption is especially important.

FIG. 3 shows a cross-sectional view of a gated diode 100. In this example, the diode 100 is formed in a bulk semiconductor substrate 102. The substrate 102 preferably is a silicon substrate but could include other semiconductors such as germanium, gallium arsenide, or silicon germanium, as examples. Shallow trench isolation (STI) regions 104 are provided to electrically isolate the diode 100 from other devices (e.g., other diodes and transistors) on the chip. Other types of isolation, such as field isolation, could alternatively be used.

The gated diode 100 includes an n+ doped region 106 and a p+ doped region 108 that are separated by a body region 110. A gate 112 overlies the body region 110 and is separated therefrom by a dielectric 114. In the illustrated embodiment, the gate includes an n-doped portion 120 adjacent a p-doped portion 122. In other embodiments, other conductors can be used to form the gate 112.

Two of the reverse leakage paths in a semiconductor gated diode 100 are illustrated in FIG. 3. The first leakage path 116 is a reverse p-n junction leakage current which scales with the area of the p-n junction. A smaller p-n junction area results in a lower leakage. The second leakage path 118 is a leakage that flows through the gate dielectric or insulator 114. The first and the second leakage paths both contribute to the reverse diode leakage current 30 indicated in FIG. 2a. As the gate dielectric becomes thinner with progressive device scaling, the second leakage component will become larger. The preferred embodiment of this invention teaches a device structure that suppresses the second leakage component, and a method for forming the device.

With the techniques of the preferred embodiment, the current flowing on the second leakage current path can be significantly reduced by using gate dielectric that comprises a high permittivity (high-k) material or dielectric with a relative permittivity εᵣ. A detailed cross-sectional view of a diode structure embodying the invention is shown in FIG. 4.

Referring now to FIG. 4, dielectric layer 114 comprises a high-k dielectric. The high-k dielectric 114 preferably has a permittivity higher than about 5, and more preferably has a permittivity higher than about 10, and even more preferably has a permittivity higher than about 20. The high permittivity dielectric 114 may be aluminum oxide (Al₂O₃), hafnium oxide (HfO₂), hafnium oxynitride (HfON), hafnium silicate (HfSiO₄), zirconium oxide (ZrO₂), zirconium oxynitride (ZrON), zirconium silicate (ZrSiO₄), yttrium oxide (Y₂O₃), lanthanum oxide (La₂O₃), cerium oxide (CeO₂), titanium oxide (TiO₂), tantalum oxide (Ta₂O₅), or a combination of two or more of these materials.

In the preferred embodiment, the high-k dielectric 114 is hafnium oxide. The gate dielectric 114 may additionally comprise another dielectric material such as silicon oxide, silicon oxynitride, or silicon nitride in addition to the high-k dielectric. In other words, the gate dielectric 114 may be a stack dielectric comprising the high-k dielectric.

The silicon oxide equivalent thickness (EOT) of the gate dielectric is preferably greater than about 5 angstroms, more preferably greater than about 10 angstroms, and even more preferably greater than about 20 angstroms. The physical thickness of the dielectric 114 may be greater than about 5 angstroms, more preferably greater than about 20 angstroms, and even more preferably greater than about 40 angstroms. In other embodiments, the physical thickness of the dielectric 114 may be smaller than about 100 angstroms, more preferably smaller than about 50 angstroms, and even more preferably smaller than about 10 angstroms.

The second leakage path 122 passes through an overlap region 124 between the gate electrode 112 and one of the doped regions 108. In the example where the anode or p-doped region 108 is electrically connected to a grounded I/O pad (see e.g., FIG. 2a) and where the cathode or n-doped region 106 is electrically connected to the supply voltage (again see e.g., FIG. 2a), the energy band diagram along the line A-A′ in FIG. 4 is depicted in FIG. 5.

The energy band diagram of FIG. 5 shows the grounded p-doped region 108 and the p-doped gate electrode region 122 biased at the supply voltage. As a result of such a bias configuration, a depletion region 126 exists in the p-doped region 108 and an accumulation region 128 exists in the p-doped portion 122 of gate electrode 112. The accumulation region is comprised of holes. Quantum mechanical tunneling of the holes from the gate electrode 122 through the dielectric 114 to the p-doped region 108 results in a leakage current. By using a high-k material for gate dielectric 114, the gate dielectric can be made thicker for the same capacitance, and the thicker gate dielectric effectively suppresses the tunneling leakage current.

Returning to FIG. 4, a conductive material 130 may be formed to strap the n-doped and p-doped regions 120 and 122 in the gate electrode 112, as well as at 134 to strap the n-doped region 106 and at 132 to strap the p-doped region 108 of the substrate. The conductive material 130 (and 132 and 134) can be a metal, a metallic nitride, a metallic silicide, or a metallic oxide, or combinations thereof. Metals such as molybdenum, tungsten, titanium, tantalum, platinum, and hafnium may be used. Metallic nitrides may be used, including but not restricted to, molybdenum nitride, tungsten nitride, titanium nitride, and tantalum nitride. Metallic silicides may be used, including but not restricted to, nickel silicide, cobalt silicide, tungsten silicide, titanium silicide, tantalum silicide, platinum silicide, and erbium silicide. Metallic oxides may also be used, including but not restricted to, ruthenium oxide, and indium tin oxide.

The isolation region 104 in FIG. 4 comprises a dielectric filling material, preferably silicon oxide. However, it is understood that any other dielectric material or combinations of dielectric materials may be used to form the isolation region.

The spacers 136 are formed on the sides of the gate electrode 112 and may comprise a dielectric material such as silicon nitride or silicon oxide. The spacers may be simple spacers as shown in FIG. 4, or the spacers may be composite spacers known and used in the art.

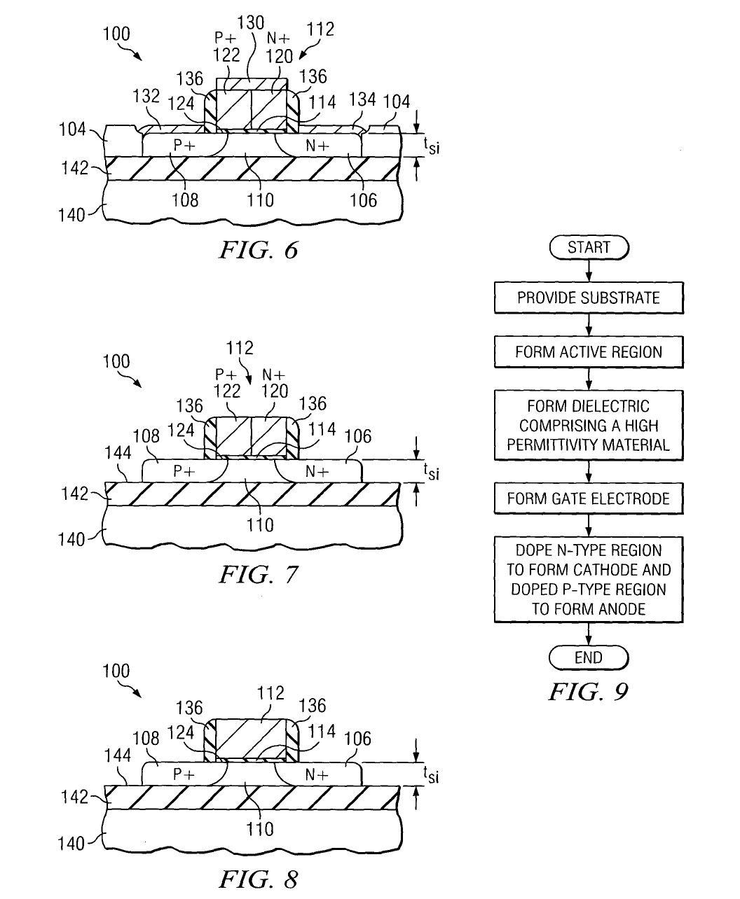

FIG. 6 shows another embodiment of the present invention where the gated diode 100 is formed on a semiconductor-on-insulator substrate. Trench isolation, in this case shallow trench isolation 104, is used in this example. In FIG. 6, the semiconductor-on-insulator substrate preferably has a silicon layer (that includes p-doped region 108, body region 110, and n-doped region 106) overlying a silicon oxide insulator layer 142, on top of a substrate 140. The thickness (t_{Si}) of silicon layer 106/108/110 is preferably in the range of about 20 angstroms to about 1000 angstroms, and more preferably in the range of about 20 angstroms to about 300 angstroms. The use of a thin silicon layer results in a small junction area and therefore a low reverse leakage.

FIG. 7 shows yet another embodiment of the invention where the gated diode 100 is formed on a semiconductor-on-insulator substrate and mesa isolation is used. By using mesa isolation, the surfaces 144 of the insulator layer 142 not covered by the semiconductor layer are exposed during the formation of the device, and the exposed insulator layer 144 may be potentially etched or recessed during chemical processing. Forming a layer of nitride to protect surfaces 144 may prevent this etching of insulator layer 142. Conductive material such as a metal silicide (not shown) may be formed on the gate electrode 112 and the doped regions 106 and 108.

FIG. 8 shows an alternative embodiment of the invention where the gate electrode 112 comprises a metal, such as metal silicide, metal nitride, or combinations thereof. While illustrated for the example of an SOI device with mesa isolation, it is understood that any of the embodiments described herein can include a metal gate. The gate electrode 112 in this embodiment does not contain poly-silicon or poly-silicon-germanium. Examples of metals include molybdenum, tungsten, titanium, tantalum, platinum, and hafnium may be used. Metallic nitrides may be used, including but not restricted to, molybdenum nitride, tungsten nitride, titanium nitride, and tantalum nitride. Metallic silicides may be used, including but not restricted to, nickel silicide, cobalt silicide, tungsten silicide, titanium silicide, tantalum silicide, platinum silicide, and erbium silicide. Metallic oxides may also be used, including but not restricted to, ruthenium oxide, and indium tin oxide.

Next, a method of forming the diode structure is described. FIG. 9 is a flowchart of process steps for forming a diode structure according to the present invention. FIGS. 10a-10f show cross-sectional views of formation of the diode as well as an n-channel and a p-channel CMOS transistor.

Referring first to FIG. 10a, an SOI substrate includes a substrate 140 with an overlying insulating layer 142 and a semiconductor layer 144. However, it will be understood that a semiconductor-on-insulator substrate or a bulk semiconductor substrate may also be used. Active regions are formed in a silicon layer of the silicon-on-insulator substrate. Three active regions 146a, 146b and 146c (collectively referred to as 146) are shown in FIG. 10b. In this example, a diode (or lubistor) will be formed in active region 146a, an n-channel transistor will be formed in active region 146b, and a p-channel transistor will be formed in active region 146c. Other active areas (not shown) will include one or more of these or other devices.

Active regions 146 are isolated in this embodiment by isolation regions, a technique known as mesa isolation. With mesa isolation, an air gap is formed between the mesa regions 146 to isolate these regions during device fabrication. Before metallization, these trench regions will be filled with a dielectric such as silicon oxide, doped glass or such. In another embodiment, shallow trench isolation is used. In this embodiment, the trenches between active areas are filled with an insulator, such as silicon oxide.

A dielectric 114 is next deposited over active regions 146. In the illustrated embodiment, dielectric 114 also covers the buried insulator 142 between the active areas 146. This result is optional. As described previously, dielectric 114 is preferably a high permittivity material. The gate dielectric 114 can be formed by a chemical vapor deposition step or a sputtering deposition step. In the preferred embodiment, the gate dielectric 114 is formed by first forming an interfacial oxide layer and then forming a high permittivity dielectric layer.

Gate electrode material 112 is next deposited on dielectric 114 and etched to form gate electrodes 112a, 112b and 112c, as shown in FIG. 10c. The gate electrode material is preferably poly-crystalline silicon, but silicon-germanium, a metal, a metal silicide, a metal nitride, a metal oxide, or combinations thereof may also be used. The gate dielectric 114 not covered by the gate electrode 112 may be removed, as shown, or may be left covering the active region 146.

Turning now to FIG. 10d, implant mask 148 is used to mask the active region 146b and a portion of the active region 146a adjacent a first edge of the gate electrode 112a. Dopants of a first type are introduced to dope regions 108 of the unmasked active regions 146, and implant mask 148 is removed. In this embodiment of the invention, dopants of the first type are p-type dopants. The dopants may also dope regions 122a of gate electrodes 112. As shown, the doping step simultaneously forms the source and drain regions 108c of the p-channel transistor in active area 146c and the p-doped region 108a of the diode in active region 146a (as well as other p-doped regions on the chip).

Next, as shown in FIG. 10e, implant mask 150 is formed so that dopants of a second type can be introduced into regions 106 of the active regions 146a and 146b and region 120 of the gate electrode 112a. In this embodiment of the invention, the dopants of the second type are n-type dopants. Implant mask 150 is removed after the introduction of dopants of the second type. As shown, the doping step simultaneously forms the source and drain regions 106b of the n-channel transistor in active area 146b and the n-doped region 106a of the diode in active region 146a (as well as other n-doped regions on the chip).

Both types of dopants may be introduced by conventional ion implantation, by plasma immersion ion implantation, or other known techniques of introducing dopants. Regions 106 and 108 are typically doped to a concentration in the range of about 10¹⁶ cm⁻³ to about 10²⁰ cm⁻³, but preferably to a concentration greater than about 10¹⁹ cm⁻³. Implant masks 148 and 150 are preferably photoresist, but may also be silicon oxide, silicon nitride, or other masking materials.

Spacers 136 may be formed on the sides of the gate electrodes 112 as shown in FIG. 10f. Additional dopants may be introduced into the active regions 146 and/or the gate electrode 112 after the formation of the spacers. These steps are included to maintain compatibility with CMOS processing used to form the n-channel and p-channel transistors on the chip. For example, the sidewall spacers 136 are formed on the transistor sidewalls and the additional dopants can be introduced during the source/drain implants of the transistors. While not shown (see e.g., FIGS. 10d and 10), masking steps are preferably used in forming the more heavily doped regions.

As shown in FIG. 10f, a conductive material 130, such as a metal silicide, may be formed on the gate electrodes 112 and on the doped regions 106 and 108 to improve their conductivity. Once again, a conductive material (see elements 130, 132 and 134 in FIG. 4 for example) can be simultaneously formed on the source, drain and gates of transistors and the doped regions and gate of the diodes that are on the same chip.

Although the present invention and its advantages have been described in detail, it should be understood that various changes, substitutions and alterations can be made herein without departing from the spirit and scope of the invention as defined by the appended claims.

1. A semiconductor diode comprising:
a substrate;
a body region formed in a portion of the substrate;
a gate dielectric overlying the body region, said gate dielectric comprising a high permittivity dielectric;
a gate electrode overlying the gate dielectric; and
a p-doped region and an n-doped region formed in the substrate oppositely adjacent to the body region.

2. The diode of claim 1 wherein the substrate is a bulk semiconductor substrate.

3. The diode of claim 2 wherein the substrate is a bulk silicon substrate.

4. The diode of claim 1 wherein the substrate comprises silicon and germanium.

5. The diode of claim 1 wherein the substrate is a silicon-on-insulator substrate comprising a silicon layer overlying an insulator layer wherein the body region, the p-doped region and the n-doped region are formed in the silicon layer.

6. The diode of claim 5 wherein the insulator layer is silicon oxide.

7. The diode of claim 5 wherein the silicon layer has a thickness in the range of about 20 angstroms to about 1000 angstroms.

8. The diode of claim 5 wherein the silicon layer has a thickness in the range of about 20 angstroms to about 300 angstroms.

9. The diode of claim 1 wherein the gate electrode comprises poly-crystalline silicon.

10. The diode of claim 9 further comprising metal silicide formed on the gate electrode, the p-doped region, and the n-doped region.

11. The diode of claim 9 wherein a first portion of the gate electrode is doped p-type and a second portion of the gate electrode is doped n-type.

12. The diode of claim 1 wherein the gate electrode is formed from a material selected from the group consisting of a metal, a metallic nitride, a metallic silicide, a metallic oxide, and combinations thereof.

13. The diode of claim 1 wherein the gate electrode is formed from a material selected from the group consisting of molybdenum, tungsten, titanium, tantalum, platinum, and hafnium.

14. The diode of claim 1 wherein the gate electrode is formed from a material selected from the group consisting of molybdenum nitride, tungsten nitride, titanium nitride, tantalum nitride, and combinations thereof.

15. The diode of claim 1 wherein the gate electrode is formed from a material selected from the group consisting of nickel silicide, cobalt silicide, tungsten silicide, titanium silicide, tantalum silicide, platinum silicide, erbium silicide, and combinations thereof.

16. The diode of claim 1 wherein the gate electrode is formed from a material selected from the group consisting of ruthenium oxide, indium tin oxide, and combinations thereof.

17. The diode of claim 1 wherein the high permittivity dielectric is selected from the group consisting of aluminum oxide, hafnium oxide, hafnium oxynitride, hafnium silicate, zirconium oxide, zirconium oxynitride, zirconium silicate, yttrium oxide, lanthanum oxide, cerium oxide, titanium oxide, tantalum oxide, and combinations thereof.

18. The diode of claim 1 wherein the high permittivity dielectric has a relative permittivity larger than about 5.

19. The diode of claim 1 wherein the high permittivity dielectric has a relative permittivity larger than about 10.

20. The diode of claim 1 wherein the high permittivity dielectric has a relative permittivity larger than about 20.

21. The diode of claim 1 wherein the gate dielectric has a physical thickness less than about 100 angstroms.

22. The diode of claim 1 wherein the gate dielectric has a physical thickness less than about 50 angstroms.

23. The diode of claim 1 wherein the gate dielectric has a physical thickness less than about 10 angstroms.

24. The diode of claim 1 wherein at least one doped region has a doping concentration of greater than about 10¹⁹ cm⁻³.

25. The diode of claim 1 and further comprising spacers on the sides of the gate electrode.

26. The diode of claim 25 wherein the material of the spacers is selected from the group consisting of silicon oxide, silicon oxynitride, silicon nitride, and combinations thereof.

27. A semiconductor device including electrostatic discharge protection, the device comprising:
a silicon-on-insulator substrate, comprising a silicon layer overlying an insulator layer;
a first doped region formed in the silicon layer and being doped with dopants of a first conductivity type;
a second doped region formed in the silicon layer and being doped with dopants of a second conductivity type, the second conductivity type being opposite the first conductivity type;
a body region formed in the silicon layer between the first doped region and the second doped region;
a high permittivity gate dielectric overlying the body region;
a gate electrode overlying the gate dielectric;
an input/output pad electrically coupled to the first doped region; and
a reference voltage node coupled to the second doped region.

28. The device of claim 27 where the insulator layer comprises silicon oxide.

29. The device of claim 27 wherein the silicon layer has a thickness in the range of about 20 angstroms to about 1000 angstroms.

30. The device of claim 27 wherein the silicon layer has a thickness in the range of about 20 angstroms to about 300 angstroms.

31. The device of claim 27 wherein the gate electrode comprises poly-crystalline silicon.

32. The device of claim 31 further comprising metal silicide formed on the gate electrode, the first doped region, and the second doped region.

33. The device of claim 31 wherein a first portion of the gate electrode is doped p-type and a second portion of the gate electrode is doped n-type.

34. The device of claim 27 wherein the gate electrode is formed from a material selected from the group consisting of a metal, a metallic nitride, a metallic silicide, a metallic oxide, and combinations thereof.

35. The device of claim 27 wherein the gate electrode is formed from a material selected from the group consisting of molybdenum, tungsten, titanium, tantalum, platinum, and hafnium.

36. The device of claim 27 wherein the gate electrode is formed from a material selected from the group consisting of molybdenum nitride, tungsten nitride, titanium nitride, tantalum nitride, and combinations thereof.

37. The device of claim 27 wherein the gate electrode is formed from a material selected from the group consisting of nickel silicide, cobalt silicide, tungsten silicide, titanium silicide, tantalum silicide, platinum silicide, erbium silicide, and combinations thereof.

38. The device of claim 27 wherein the gate electrode is formed from a material selected from the group consisting of ruthenium oxide, indium tin oxide, and combinations thereof.

39. The device of claim 27 wherein the high permittivity dielectric is selected from the group consisting of aluminum oxide, hafnium oxide, hafnium oxynitride, hafnium silicate, zirconium oxide, zirconium oxynitride, zirconium silicate, yttrium oxide, lanthanum oxide, cerium oxide, titanium oxide, tantalum oxide, and combinations thereof.

40. The device of claim 27 wherein the high permittivity dielectric has a relative permittivity larger than about 5.

41. The device of claim 27 wherein the high permittivity dielectric has a relative permittivity larger than about 10.

42. The device of claim 27 wherein the high permittivity dielectric has a relative permittivity larger than about 20.

43. The device of claim 27 wherein the gate dielectric has a physical thickness less than about 100 angstroms.

44. The device of claim 27 wherein the gate dielectric has a physical thickness less than about 50 angstroms.

45. The device of claim 27 wherein the gate dielectric has a physical thickness less than about 10 angstroms.

46. The device of claim 27 wherein at least one doped region has a doping concentration of greater than 10¹⁹ cm⁻³.

47. The device of claim 27 further comprising spacers on the sides of the gate electrode.

48. The device of claim 47 wherein the spacers comprise a material selected from the group consisting of silicon oxide, silicon oxynitride, silicon nitride, and combinations thereof.

49. The device of claim 27 wherein the first doped region comprises a p-type region that is electrically coupled to the input/output pad and the second doped region comprises an n-type region that is electrically coupled to a V_{DD} power supply.

50. The device of claim 27 wherein the second doped region comprises a p-type region that is electrically coupled to a ground line and the second doped region comprises an n-type region that is electrically coupled to the input/output pad.

51. A method of forming a diode, the method comprising:
providing a silicon-on-insulator substrate including a silicon layer overlying an insulator layer;
creating an active region in the silicon layer;
forming a gate dielectric on the active region, the gate dielectric comprising a high permittivity dielectric;
forming a gate electrode on the gate dielectric;
forming a p-doped region in the active region adjacent a first edge of the gate electrode; and
forming an n-doped region in the active region adjacent a second edge of the gate electrode, the first edge being opposed to the second edge.

52. The method of claim 51 wherein the steps of forming a p-doped region and forming an n-doped region comprise:
forming a first implant mask exposing a first portion of the active region;
doping the first portion of the silicon layer;
forming a second implant mask exposing a second portion of the active region; and
doping the second portion of the silicon layer.

53. The method of claim 51 further comprising:
forming isolation regions surrounding the active region; and
doping the active region.

54. The method of claim 51 wherein the p-doped region and the n-doped region are doped to a dopant concentration greater than about 10¹⁹ cm⁻³.

55. The method of claim 51 wherein forming the gate dielectric comprises a chemical vapor deposition step or a sputtering deposition step.

56. The method of claim 51 wherein forming the gate dielectric comprises:
forming an interfacial oxide layer; and
forming a high permittivity dielectric layer.

57. The method of claim 51 further comprising the step of creating spacers on sides of the gate electrode.

58. The method of claim 57 wherein the material of the spacers is selected from the group composed of silicon oxide, silicon oxynitride, silicon nitride, and combinations thereof.

59. The method of claim 51 wherein the silicon layer has a thickness in the range of about 20 angstroms to about 1000 angstroms.

60. The method of claim 51 wherein the silicon layer has a thickness in the range of about 20 angstroms to about 300 angstroms.

61. The method of claim 51 wherein the gate electrode comprises poly-crystalline silicon.

62. The method of claim 61 further comprising the step of forming a metal silicide on the gate electrode, the p-doped region, and the n-doped region.

63. The method of claim 51 wherein the gate electrode comprises a material selected from the group consisting of a metal, a metallic nitride, a metallic silicide, a metallic oxide, and combinations thereof.

64. The method of claim 51 wherein the gate electrode comprises a material selected from the group consisting of molybdenum, tungsten, titanium, tantalum, platinum, and hafnium.

65. The method of claim 51 wherein the gate electrode comprises a material selected from the group consisting of molybdenum nitride, tungsten nitride, titanium nitride, tantalum nitride, and combinations thereof.

66. The method of claim 51 wherein the gate electrode comprises a material selected from the group consisting of nickel silicide, cobalt silicide, tungsten silicide, titanium silicide, tantalum silicide, platinum silicide, erbium silicide, and combinations thereof.

67. The method of claim 51 wherein the gate electrode comprises a material selected from the group consisting of ruthenium oxide, indium tin oxide, and combinations thereof.

68. The method of claim 51 wherein the high permittivity dielectric is selected from the group consisting of aluminum oxide, hafnium oxide, hafnium oxynitride, hafnium silicate, zirconium oxide, zirconium oxynitride, zirconium silicate, yttrium oxide, lanthanum oxide, cerium oxide, titanium oxide, tantalum oxide, and combinations thereof.

69. The method of claim 51 wherein the high permittivity dielectric has a relative permittivity larger than about 5.

70. The method of claim 69 wherein the high permittivity dielectric has a relative permittivity larger than about 10.

71. The method of claim 70 wherein the high permittivity dielectric has a relative permittivity larger than about 20.

72. The method of claim 51 wherein the gate dielectric has a physical thickness of less than about 100 angstroms.

73. The method of claim 72 wherein the gate dielectric has a physical thickness less than about 50 angstroms.

74. The method of claim 73 wherein the gate dielectric has a physical thickness less than about 10 angstroms.

75. A method of simultaneously forming a diode and a plurality of CMOS transistors, the method comprising:
providing a silicon layer including a plurality of isolation regions, the isolation regions creating first, second and third active regions;
forming a gate dielectric on each of the first, second and third active regions, the gate dielectric comprising a high permittivity dielectric;
forming a gate electrode layer over the gate dielectric;
etching the gate electrode layer to form a first gate electrode over the first active region, a second gate electrode over the second active region, and a third gate electrode over the third active region;
masking the first active region and a portion of the second active region adjacent a first edge of the second gate electrode;
implanting p-type dopants into the third active region and an unmasked portion of the second active region;
masking the third active region and a portion of the second active region adjacent a second edge of the second gate electrode; and
implanting n-type dopants into the first active region and an unmasked portion of the second active region adjacent the first edge of the second gate electrode.

76. The method of claim 75 wherein the silicon layer comprises a top portion of a bulk semiconductor substrate.

77. The method of claim 75 wherein the silicon layer comprises a silicon layer that overlies an insulating layer.

78. The method of claim 75 wherein forming the gate dielectric comprises:
forming an interfacial oxide layer; and
forming a high permittivity dielectric layer.

79. The method of claim 75 further comprising:
forming spacers on sides of each gate electrode;
masking the first active region and the portion of the second active region adjacent the first edge of the second gate electrode;
implanting p-type dopants into the third active region and the portion of the second active region adjacent the second edge of the second gate electrode;
masking the third active region and the portion of the second active region adjacent a second edge of the second gate electrode; and
implanting n-type dopants into the first active region and the portion of the second active region adjacent the first edge of the second gate electrode.

80. The method of claim 75 wherein the gate electrode comprises poly-crystalline silicon.

81. The method of claim 75 wherein the gate electrode comprises a material selected from the group consisting of molybdenum, tungsten, titanium, tantalum, platinum, and hafnium.

82. The method of claim 75 wherein the gate electrode comprises a material selected from the group consisting of molybdenum nitride, tungsten nitride, titanium nitride, tantalum nitride, and combinations thereof.

83. The method of claim 75 wherein the gate electrode comprises a material selected from the group consisting of nickel silicide, cobalt silicide, tungsten silicide, titanium silicide, tantalum silicide, platinum silicide, erbium silicide, and combinations thereof.

84. The method of claim 75 wherein the gate electrode comprises a material selected from the group consisting of ruthenium oxide, indium tin oxide, and combinations thereof.

85. The method of claim 75 wherein the high permittivity dielectric comprises hafnium oxide.

86. The method of claim 75 wherein the high permittivity dielectric is selected from the group consisting of aluminum oxide, hafnium oxynitride, hafnium silicate, zirconium oxide, zirconium oxynitride, zirconium silicate, yttrium oxide, lanthanum oxide, cerium oxide, titanium oxide, tantalum oxide, and combinations thereof.

87. The method of claim 75 wherein the high permittivity dielectric has a relative permittivity larger than about 10.

88. The method of claim 87 wherein the high permittivity dielectric has a relative permittivity larger than about 20.

89. The method of claim 75 wherein the gate dielectric has a physical thickness less than about 10 angstroms.
